(19) United States
(12) Patent Application Publication
(10) Pub. No.: US 2013/0242519 A1
(43) Pub. Date: Sep. 19, 2013

(54) PRINTED CIRCUIT BOARD

(71) Applicants: FU-LI GAO, Shenzhen City (CN); KUO-PIN LIN, Tu-Cheng (TW)

(72) Inventors: FU-LI GAO, Shenzhen City (CN); KUO-PIN LIN, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/454,027

(22) Filed: Apr. 23, 2012

(30) Foreign Application Priority Data
Mar. 19, 2012 (CN) 201210071359.9

(51) Int. Cl. H05K 7/06; H05K 1/09; H05K 1/16

(52) U.S. Cl. 361/781; 174/260; 174/257

(57) ABSTRACT

A printed circuit board includes an insulating layer and a conductive metal layer attached on the insulating layer. The conductive metal layer is grounded and is configured for providing a ground path for electronic components mounted on the printed circuit board. The insulating layer includes an exposed portion free of the conductive metal layer thereon, and two pads are formed on the exposed portion of the insulating layer and are insulated from each other. An inductor is mounted on the exposed portion and is electrically connected to the two pads.

### BACKGROUND

1. Technical Field

The present disclosure relates to structure and layout of printed circuit boards and, particularly, to a structure and layout of a printed circuit board capable of reducing electromagnetic interference.

2. Description of Related Art

Most electromagnetic interference generated in a printed circuit board can be reduced by a ground connection. However, a poor layout of a ground layer may strengthen the electromagnetic interference.

For example, referring to FIG. 1, a printed circuit board 100′ of an electronic device, such as a Digital Versatile Disc (DVD) player, includes a power switch circuit (not shown) used for repeatedly charging and discharging. A copper foil (shown as the shadow) 20′ laid on the entire printed circuit board 100′ is connected to ground, to form a high current ground loop, which is capable of reducing any electromagnetic interference generated in the printed circuit board 100′.

The electronic components in the printed circuit board 100′, such as a Power Management IC, include a ground pin to form a ground loop, and then connect to the high current ground loop formed by the copper foil 20′ via the ground pin, thus eliminating or reducing the electromagnetic interference generated therein. However, an inductor used for repeatedly charging and discharging and included in the power switch circuit and connected to the printed circuit board 100′ by pads 303′ and 304′ does not include a ground pin. Therefore, the high-order harmonic distortion and noise generated by the inductor during the process of repeatedly charging and discharging can only be reduced or eliminated by the copper foil covered by the inductor. But because the path of a loop formed by the ground connection of the printed circuit board 100′ and the copper foil covered by the inductor is long, a portion of high-order harmonic distortion and noise may flow to other electronic components of the printed circuit board 100′ via the copper foil 20′ during the process that the high-order harmonic distortion and noise are conducted to ground, thus increasing the adverse influence of the electromagnetic interference on the other electronic components.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a layout diagram of a printed circuit board in an electronic device of related art.

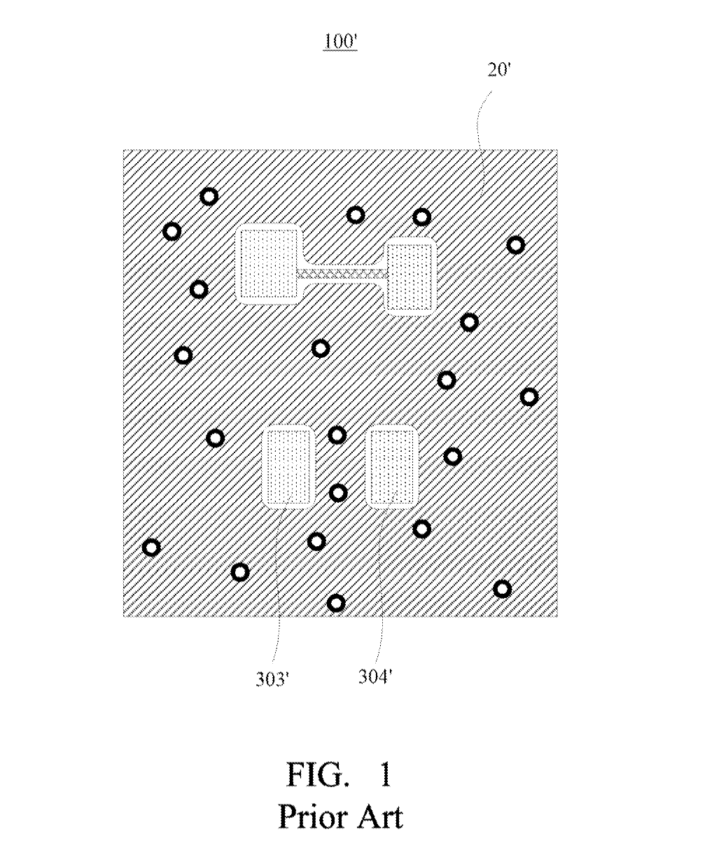

FIG. 2 is a layout diagram of a new printed circuit board in an electronic device, according to an embodiment.

FIG. 3 is the layout diagram of the printed circuit board of FIG. 2, showing an inductor soldered on the printed circuit board.

### DETAILED DESCRIPTION

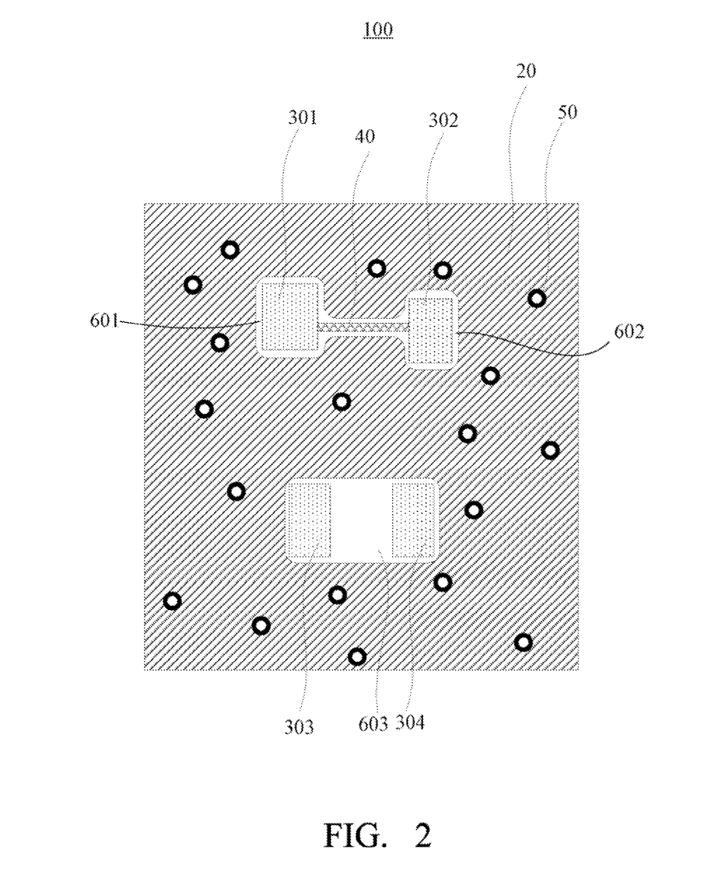

For use in an electronic device (such as DVD player), FIG. 2 shows a layout of a printed circuit board 100 capable of reducing electromagnetic interference. The printed circuit board 100 includes an insulating layer, a conductive metal layer (shown as the shadow) 20, a number of pads, such as pads 301˜304 for soldering connecting electronic components, and a number of printed conductors 40 for connecting electronic components. FIG. 2 only shows a portion layout of the printed circuit board 100, in the embodiment, the printed circuit board 100 includes a power switch circuit.

In the embodiment, the conductive metal layer 20 is attached on the insulating layer, and is connected to an internal ground of the printed circuit board 100 for providing a ground path for electronic components mounted on the printed circuit board 100. In the embodiment, the conductive metal layer 20 is a grounded copper foil attached on the insulating layer and is for absorbing the electromagnetic interference generated in the printed circuit board 100. In the embodiment, the insulating layer includes a number of exposed portions 601˜603 free of the conductive metal layer thereon, and pads 301˜304 and the printed conductors 40 are formed on the exposed portions of the insulating layer and are insulated from each other. Thus, the conductive metal layer 20 is separated from the pads 301˜304 and the printed conductors 40 to avoid short-circuits. A number of grounding holes 50 connected to the internal ground of the printed circuit board 100 are arranged in the conductive metal layer 20 for radiating heat energy and providing space for thermal expansion.

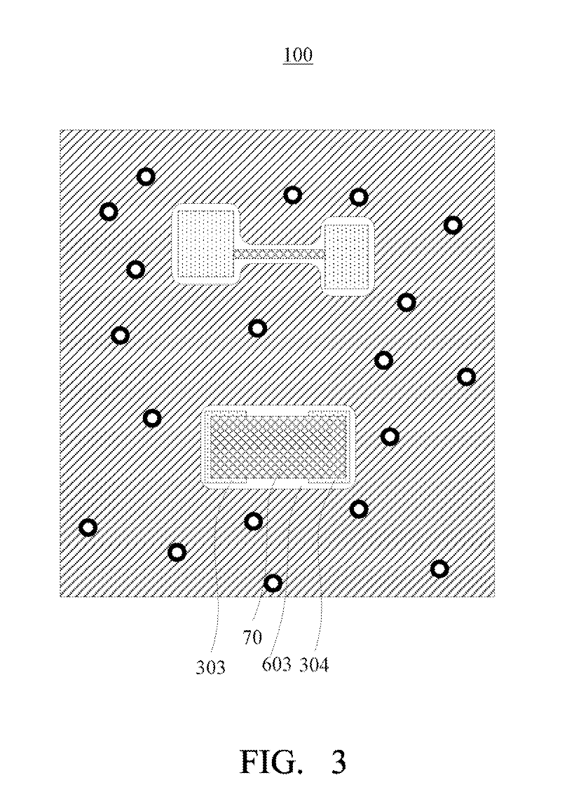

Referring to FIG. 3, the power switch circuit includes an inductor 70 for charging and discharging repeatedly. In the embodiment, the inductor 70 is a chip inductor and is connected to the power switch circuit by being mounted on the exposed portion 603 and being electrically connected to the two pads 303 and 304. The two pads 303 and 304 are insulated from each other and a predetermined area between the two pads 303 and 304 is not covered by copper foil 20. Thereby a spread path of a high-order harmonic distortion and noise generated by charging and discharging process of the inductor 70 is cut off to prevent high-order harmonic distortion and noise going to other components on the printed circuit board 100. Therefore, the incidence or amount of the electromagnetic interference on the other electronic components is effectively reduced.

Moreover, it is to be understood that the disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A printed circuit board comprising:
an insulating layer;
a conductive metal layer attached on the insulating layer, the conductive metal layer grounded and configured for providing grounding for electronic components mounted on the printed circuit board, the insulating layer comprising an exposed portion free of the conductive metal layer thereon;
two pads formed on the exposed portion of the insulating layer and insulated from each other; and
an inductor mounted on the exposed portion and electrically connected to the two pads.

2. The printed circuit board according to claim 1, wherein the conductive metal layer is a grounded copper foil attached on the insulating layer.

3. The printed circuit board according to claim 1, wherein the inductor is a chip inductor.

4. The printed circuit board according to claim 1, further comprising a power switch circuit.
